(19) United States
(12) Patent Application Publication
(10) Pub. No.: US 2026/0267816 A1
(43) Pub. Date: Sep. 10, 2026

(54) INPUT-OUTPUT MODULE, FREQUENCY CONVERSION MODULE, CONTROL METHODS AND CHIP

(71) Applicants: Beijing BOE Technology Development Co., Ltd., Beijing (CN); BOE Technology Group Co., Ltd., Beijing (CN)

(72) Inventors: Jianwen ZHU, Beijing (CN); Binhua SUN, Beijing (CN); Feng ZI, Beijing (CN)

(73) Assignees: Beijing BOE Technology Development Co., Ltd., Beijing (CN); BOE Technology Group Co., Ltd., Beijing (CN)

(21) Appl. No.: 18/994,693

(22) PCT Filed: Jul. 31, 2023
(86) PCT No.: PCT/CN2023/110372

§ 371 Date: Jan. 15, 2025

(51) Int. Cl. G06F 13/40; H03K 3/037; H03K 5/00

(52) U.S. Cl. CPC G06F 13/4022; H03K 3/037; H03K 5/00006

(57) ABSTRACT

An input-output module and control method therefor, a chip and a virtual reality apparatus are described. The input-output module has M input pins, a path switcher, a shift register and a flip-flop connected in sequence, the flip-flop having N output pins; wherein the M input pins comprise a path pin, an instruction pin, and a shift pin, output levels of the N output pins are configured to control whether to power on a plurality of devices or not; and the path switcher is configured to store, in response to an input signal of the path pin, an enable signal received from the instruction pin into the shift register, and the shift register is configured to output, in response to a shift signal of the shift pin, the stored enable signal to the flip-flop to control the output levels of the N output pins.

### CROSS-REFERENCE TO RELATED APPLICATION

The present application is a national stage of International Application No. PCT/CN2023/110372 filed on Jul. 31, 2023, the contents of which are incorporated herein by reference in its entirety.

### TECHNICAL FIELD

The present disclosure relates to the field of virtual reality technologies, and in particular to an input-output module, a frequency conversion module, control methods and a chip.

### BACKGROUND OF THE INVENTION

With the development of eye tracking technology, various virtual reality (VR) or augmented reality (AR) software applications have increasing requirements for the refresh rate of eye tracking. To meet the requirements of various VR/AR software applications for the refresh rate of eye tracking, an eye tracking system in a VR/AR headset uses a large number of devices, for example, infrared cameras, camera drive modules, and fill lights, which, however, increases the average power consumption and reduces the running time of the eye tracking system and the battery life of the whole apparatus.

In the related art, in order to reduce the average power consumption of the eye tracking system and increase the running time of the eye tracking system and the battery life of the whole apparatus, individual devices in the eye tracking system are connected to a system on chip (SOC), respectively, and are controlled in a parallel control mode, such that these devices can only be powered on and run when they are needed to work.

However, the parallel control over the plurality of devices in the eye tracking system leads to the occupation of a large number of SOC resources by the eye tracking system in the VR/AR headset, which in turn often leads to insufficient resources of the SOC.

### SUMMARY OF THE INVENTION

Embodiments of the present disclosure provide an input-output module, a frequency conversion module, control methods and a chip, whereby whether to power on a large number of devices can be controlled in a case where a small number of ports of an SOC are occupied, thereby saving the resources of the SOC. The technical solutions are as follows.

According to an aspect of the embodiments of the present disclosure, an input-output module is provided. The input-output module includes:
M input pins, a path switcher, a shift register, and a flip-flop connected in sequence, the flip-flop having N output pins,
wherein the M input pins are configured to receive input signals, and include a path pin, an instruction pin, and a shift pin, the N output pins are configured to connect a plurality of devices of an apparatus, respectively, output levels of the N output pins are configured to control whether to power on the plurality of devices or not, and M and N are positive integers; and
the path switcher is configured to store, in response to an input signal of the path pin, an enable signal received from the instruction pin into the shift register, and the shift register is configured to output, in response to a shift signal of the shift pin, the stored enable signal to the flip-flop to control the output levels of the N output pins.

According to a second aspect of the embodiments of the present disclosure, a control method applied to the input-output module as defined above is provided. The method includes:
sending an input signal to the path pin, for controlling the path switcher to store the enable signal received from the instruction pin into the shift register; and
sending a shift signal to the shift pin, for controlling the shift register to output the stored enable signal to the flip-flop so as to control the output levels of the N output pins.

According to a third aspect of the embodiments of the present disclosure, a chip is provided. The chip includes the input-output module as defined above.

According to a fourth aspect of the embodiments of the present disclosure, a virtual reality apparatus is provided. The virtual reality apparatus includes a plurality of cameras. Each of the cameras is connected to the chip as defined above, respectively, for controlling whether to power on each of the cameras, respectively, by means of the chip.

According to a fifth aspect of the embodiments of the present disclosure, a frequency conversion module is provided. The frequency conversion module includes:
a parser and a plurality of frequency multipliers, wherein each of the frequency multipliers is connected to the parser, respectively, and is connected to a device of an apparatus, respectively;
the parser is configured to parse acquired data to be parsed to acquire a plurality of sets of frequency conversion data, each of which includes an identifier of frequency multiplier and a frequency conversion value, and configured to send each set of the frequency conversion data to a corresponding frequency multiplier, respectively, based on the identifier of frequency multiplier in each set of the frequency conversion data; and
each of the frequency multipliers is configured to multiply an input frequency based on the received frequency conversion value to acquire a target frequency, which represents an operating frequency of the device.

According to a sixth aspect of the embodiments of the present disclosure, a control method applied to the frequency conversion module as defined above is provided. The method includes:
sending data to be parsed to the parser, and controlling the parser to parse the data to be parsed to acquire a plurality of sets of frequency conversion data, each of which includes the identifier of frequency multiplier and the frequency conversion value;
controlling the parser to send each set of the frequency conversion data to a matching frequency multiplier, respectively, based on the identifier of frequency multiplier in each set of the frequency conversion data; and
controlling the frequency multiplier to multiply the input frequency based on the received frequency conversion value to acquire the target frequency, which represents the operating frequency of the device.

According to a seventh aspect of the embodiments of the present disclosure, a chip is provided. The chip includes the frequency conversion module as defined above.

According to an eighth aspect of the embodiments of the present disclosure, a virtual reality apparatus is provided. The virtual reality apparatus includes the chip as defined above.

### BRIEF DESCRIPTION OF DRAWINGS

For clearer descriptions of the technical solutions in the embodiments of the present disclosure, the following briefly introduces the accompanying drawings required for describing the embodiments. Apparently, the accompanying drawings in the following description show merely some embodiments of the present disclosure, and persons of ordinary skill in the art may still derive other drawings from these accompanying drawings without creative efforts.

FIG. 1 is a schematic diagram of an implementation environment according to an embodiment of the present disclosure;

FIG. 2 is a schematic structural diagram of an input-output module according to an embodiment of the present disclosure;

FIG. 3 is a schematic structural diagram of external connections of an input-output module according to an embodiment of the present disclosure;

FIG. 4 is a schematic flowchart of a control method applied to an input-output module according to an embodiment of the present disclosure;

FIG. 5 is an exemplary schematic flowchart of a control method for an input-output module according to an embodiment of the present disclosure;

FIG. 6 is a schematic structural diagram of a frequency conversion module according to an embodiment of the present disclosure;

FIG. 7 is a schematic structural diagram of an enabled fill light according to an embodiment of the present disclosure;

FIG. 8 is a schematic flowchart of a control method applied to a frequency conversion module according to an embodiment of the present disclosure;

FIG. 9 is a exemplary schematic flowchart of a control method applied to a frequency conversion module according to an embodiment of the present disclosure; and

FIG. 10 is a schematic structural diagram of a plurality of devices that are connected to a frequency conversion module and an input-output module, respectively, according to an embodiment of the present disclosure.

### DETAILED DESCRIPTION

For clearer descriptions of the objectives, technical solutions, and advantages of the present disclosure, embodiments of the present disclosure are described in detail hereinafter with reference to the accompanying drawings.

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the present disclosure. Instead, they are merely examples of apparatuses and methods consistent with aspects related to the present disclosure as recited in the appended claims.

The terms “first”, “second”, or the like in the present disclosure are intended to distinguish the same or similar items with substantially the same effects and functions. It should be understood that “first”, “second”, and “nth” show no logical or chronological dependence therebetween, or limit the number or the order of execution. It should also be understood that although the terms first, second, or the like are used in the following description to describe various elements, these elements should not be limited by these terms.

These terms are simply intended to distinguish one element from another. For example, without departing from the scope of various examples, a first action may be called a second action, and similarly, the second action may be also called the first action. Both the first and second actions may be actions and, in some cases, may be separate and different actions.

“At least one” refers to one or more. For example, at least one action may refer to one action, two actions, three actions, or any integer number of actions, with the integer number greater than or equal to one. Furthermore, “a plurality of” refers to two or more. For example, a plurality of actions may refer to two actions, three actions, or any integer number of actions, with the integer number greater than or equal to two.

It should be noted that the data (including but not limited to training data and data for prediction, for example, user data, terminal-side data, or the like) and signals involved in the present disclosure are all authorized by the user or fully authorized by all parties, and the acquisition, use and processing of relevant data shall comply with the relevant laws, regulations and standards in relevant countries and regions. For example, the training data involved in the present disclosure are all acquired with full authorization.

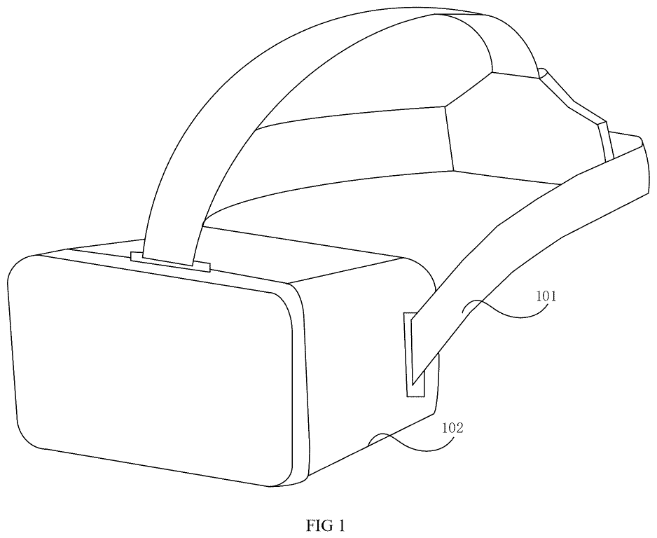

FIG. 1 is a schematic diagram of an implementation environment according to an embodiment of the present disclosure. The implementation environment provides a virtual reality apparatus for simulating a three-dimensional (3D) virtual environment for a user, and the virtual reality apparatus may be a VR apparatus or an AR apparatus, for example, VR glasses or VR helmet. The virtual reality apparatus includes a wearable module 101 and a display module 102. The display module 102 is configured to display an image at the head of the user, who may select an application icon based on the display module 102 for launching any game or the like, and the display module 102 includes a display screen. The wearable module 101 includes eyeglass temples or an elastic band for wearing the virtual reality apparatus on the head of the user.

In some embodiments, a processor as well as a memory are integrated inside the virtual reality apparatus. The processor is configured to model a 3D virtual environment by generating 3D display pictures corresponding to the 3D virtual environment, generating virtual objects in the 3D virtual environment, or the like. The memory is configured to store computer programs or data required by the processor for modeling the 3D virtual environment. The processor and the memory are connected to the VR apparatus via a port or a flexible circuit board, respectively. The processor is an SOC.

In some embodiments, the virtual reality apparatus is also provided with a camera for eye tracking, for example, an infrared camera. The camera is connected to a port of the SOC, and is disposed above the display module and configured to track the motions of the pupils and fixation of the user and provide feedback on the tracked motions of the pupils and fixation of the user to the SOC.

In some embodiments, the virtual reality apparatus is further provided with a motion sensor. The motion sensor is connected to a port of the SOC, and is configured to capture the head motion of the user and provide feedback on the captured head motion to the SOC, such that the SOC changes a displayed picture in the display module 102 based on the head motion of the user.

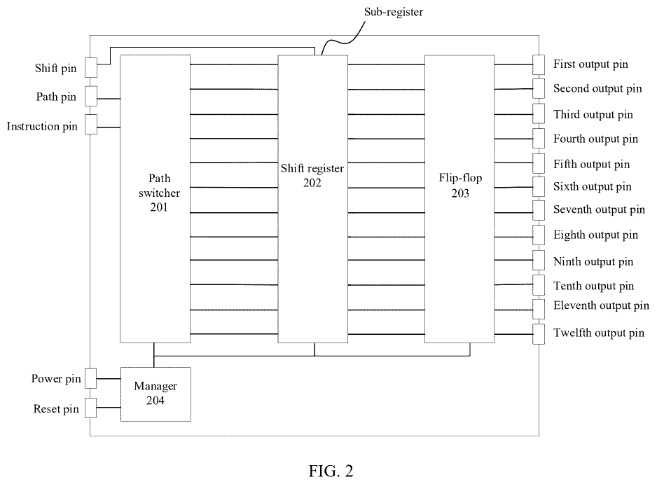

FIG. 2 is a schematic structural diagram of an input-output module according to an embodiment of the present disclosure. As shown in FIG. 2, the module includes: M input pins connected sequentially, a path switcher 201, a shift register 202, and a flip-flop 203 having N output pins.

The input pins are configured to receive input signals or input levels, and the output pins of the flip-flop 203 are configured to output levels.

The path switcher 201 is configured to turn on N different storages sites of the shift register 202 based on N input signals, and transmit N input levels to the N different storage sites in the shift register 202, respectively.

The shift register 202 is configured to store the received N input levels, and transmit the N input levels to the flip-flop 203, respectively.

The flip-flop 203 is configured to determine the output levels of the N output pins based on the N input levels.

In some embodiments, M is less than N, the M input pins are connected to the SOC, the N output pins of the flip-flop 203 are connected to N devices, respectively, and the input-output module is powered on and started, such that the SOC controls whether to power on the N devices based on the input-output module.

In some embodiments, the M input pins are configured to receive input signals, and include a path pin, an instruction pin, and a shift pin; the N output pins are configured to connect a plurality of devices of an apparatus, respectively; the output levels of the N output pins are configured to control whether to power on the plurality of devices or not; and M and N are positive integers.

Here, each of the input pins is connected to one port of the SOC in the VR/AR apparatus, respectively; each of the output pins of the flip-flop 203 is connected to one device of the apparatus, respectively, and is configured to control, by means of the output level of each of the output pins of the flip-flop 203, whether to power on the device connected to said output pin of the flip-flop 203.

The SOC controls a timing sequence for sending individual signals to the path pin, the instruction pin, and the shift pin.

In some embodiments, the port is a general-purpose input-output (GPIO) port.

In some embodiments, the SOC is disposed inside the VR/AR apparatus, and is configured to control the working states of a plurality of devices in the VR/AR apparatus.

In some embodiments, the input-output module is further provided with a manager 204 and a reset pin; the output terminal of the reset pin is connected to the output terminal of the manager 204; the input terminal of the reset pin is connected to one terminal of the SOC; the manager 204 is connected to the path switcher 201, the shift register 202, and the flip-flop 203, respectively; and the manager 204 controls, in response to the reset signal of the reset pin, the path switcher 201, the shift register 202, and the flip-flop 203 respective to perform resetting, respectively, such that the path switcher 201, the shift register 202, and the flip-flop 203 are each in an initial state. The embodiments of the present disclosure do not make specific definitions to the manager 204.

In some embodiments, the input-output module is further provided with a power pin; the input terminal of the power pin is connected to any power supply apparatus; the output terminal of the power pin is connected to the manager 204; and the manager 204 supplies power to the path switcher 201, the shift register 202, and the flip-flop 203, respectively, based on the alternating current or direct current transmitted by the power pin. The embodiments of the present disclosure do not make specific definitions to the power supply apparatus.

In some embodiments, a plurality of devices in the VR/AR apparatus are all cameras; M=3, and N=12; the path pin, the instruction pin, and the shift pin are each connected to one port of the SOC, respectively; and the 12 output pins of the input-output module are connected to 12 cameras, respectively. The embodiments of the present disclosure do not make specific definitions to the camera.

In some embodiments, the path switcher 201 is configured to store, in response to an input signal of the path pin, an enable signal received from the instruction pin into the shift register 202; and the shift register 202 is configured to output, in response to a shift signal of the shift pin, the stored enable signal to the flip-flop 203 to control the output levels of the N output pins.

Here, the input signal includes any one of the path switching signal, the enable signal, and the shift signal.

In some embodiments, the path switcher 201 stores a plurality of enable signals into the shift register 202 in response to the input signals of the path pin and instruction pin; the shift register 202 outputs the stored enable signals to the flip-flop 203 in response to the shift signal of the shift pin, so as to control the output levels of the 12 output pins of the flip-flop 203; and thus, by means of the output level of each output pin of the flip-flop 203, whether to power on the camera connected to said output pin of the flip-flop 203 is controlled, thereby allowing for control of the power-on/off of the 12 cameras of the VR/AR apparatus based on the 3 ports of the SOC, which saves the resources of 9 ports of the SOC compared with the related art.

According to the embodiments of the present disclosure, the input-output module with the output pins having the number greater than that of its input pins is disposed on the ports of the SOC, and the plurality of output pins of the input-output module are connected to a plurality of devices, respectively, whereby whether to power on a large number of devices can be controlled in a case where a small number of ports of the SOC are occupied, thereby saving the resources for the SOC; furthermore, the SOC independently enables each of the output pins of the input-output module, and then allows for independent drive of the plurality of devices connected to the individual output pins, respectively.

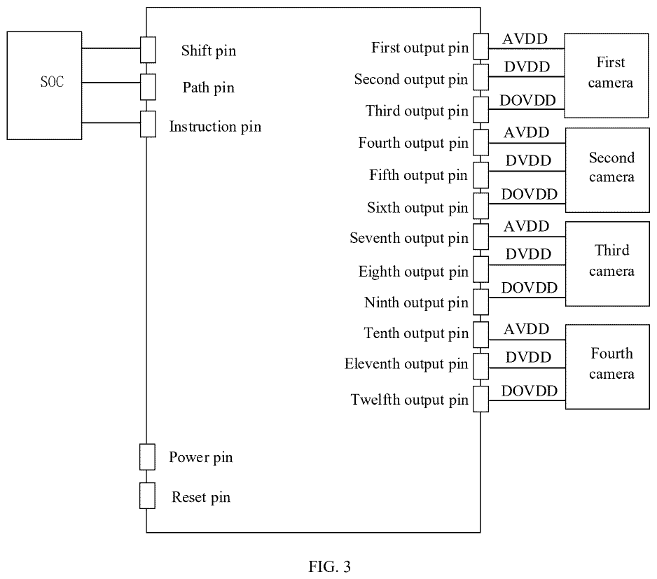

FIG. 3 is a schematic structural diagram of external connections of the input-output module shown in FIG. 2.

In some embodiments, as shown in FIG. 3, the shift register includes a plurality of sub-registers, the path switcher includes a plurality of path switches in one-to-one correspondence with the sub-registers, and the path switcher is configured to receive a path switching signal from the path pin, and turn on a path switch indicated by the path switching signal to thus turn on a sub-register in the shift register corresponding to the path switch; and the path switcher is configured to receive the enable signal from the instruction pin, and transmit the enable signal to the sub-register; and the shift register is configured to receive the shift signal from the shift pin, and output the stored enable signal to the flip-flop.

In some embodiments, the shift register includes 12 sub-registers. Every time when receiving a path switching signal from the path pin and parsing the path switching signal to acquire a parsing result, the path switcher turns on one path switch indicated by the parsing result, thereby turning on the sub-register in the shift register corresponding to said path switch. For example, the path switcher performs a decoding operation on the path switching signal based on a logic signal decoder; and in a case where a data packet corresponding to a path switching signal is “10101 0111 11011” with “10101” as a header, “11011” as a tail, and “0111” being a binary “7” in the data packet, the parsing result is “7”, indicating the seventh sub-register. The embodiments of the present disclosure do not make specific definitions to the logical signal decoder.

In some embodiments, the shift register includes 12 sub-registers. Every time when receiving the L^{th} path switching signal from the path pin, the path switcher turns on the Lth path switch, thereby turning on the L^{th} sub-register. Here, L is an integer that is greater than or equal to 1 and less than or equal to 12. For example, after the input-output module resets, the path switcher turns on a first sub-register when receiving a first path switching signal (for example, “1”) from the path pin, and turn on a tenth sub-register when receiving a tenth path switching signal from the path switcher, till all the 12 sub-registers are turned on.

In some embodiments, ever time when one sub-register is turned on, the path switcher transmits the received one enable signal to said sub-register, which stores the received enable signal.

In some embodiments, after each of the sub-registers in the shift register stores the enable signal, respectively, the shift register receives the shift signal. For example, when all the 12 sub-registers in the shift register store the enable signals, the shift register receives the shift signal from the shift pin, and transmits the enable signal in each of the sub-registers to the flip-flop.

In some embodiments, the path switcher includes a plurality of path switches in one-to-one correspondence with these sub-registers.

In some embodiments, every time when receiving one path switching signal from the path pin, the path switcher turns on one sub-register corresponding to the path switch, to allow the path switcher to transmit one enable signal received from the instruction pin to said sub-register.

In some embodiments, the output pins included by the flip-flop are in one-to-one correspondence with the sub-registers; the flip-flop is configured to flip-flop, in a case where an enable signal received from any of the sub-registers is of a high level, an output level of the corresponding output pin; or the flip-flop is configured to maintain, in a case where an enable signal received from any one of the sub-registers is of a low level, an output level of the corresponding output pin.

In some embodiments, the flip-flop includes 12 toggle paths; the input pins of the individual toggle paths are in one-to-one correspondence with the sub-registers; and the output pins of the individual toggle paths of the flip-flop are in one-to-one correspondence with the devices. After the shift register receives the shift signal from the shift pin, the enable signal stored in each of the sub-registers is sent to the input pin of the individual toggle paths, respectively; and after the individual toggle paths receive the enable signals from the input pins, the enable signals are transmitted to control circuits of the individual toggle paths of the flip-flop, respectively.

It should be noted that the output pins of the individual toggle paths of the flip-flop are each provided with one control circuit, which is configured to control whether to flip-flop the output level of the output pin; each enable signal is only configured to control the control circuit of one of the output pins of the flip-flop; when the enable signal is of a high level, the control circuit is toggled to flip-flop the output level of the output pin, such that the output level of the output pin is flip-flopped from a low level to a high level, or from a high level to a low level; and when the enable signal is of a low level, the control circuit is not toggled to flip-flop the output level of the output pin of the control circuit, such that the output level of the output pin remain unchanged (that is, the output level of the output pin does not change).

In some embodiments, after the flip-flop performs resetting, the output level of the output pin of each of the toggle paths of the flip-flop is in an initial state and of a low level, and when an enable signal transmitted to an output pin of the flip-flop is of a high level, the output level of said output pin of the flip-flop is flip-flopped, such that the output level is converted from the low level to the high level; and when an enable signal transmitted to an output pin of the flip-flop is of a low level, the output level of said output pin of the flip-flop is remained at the low level without flip-flopping. Here, when the output level of the output pin of the flip-flop is of the high level, a camera connected to said output pin of the flip-flop is controlled to be powered on; and when the output level of the output pin of the flip-flop is of the low level, a camera connected to said output pin of the flip-flop is controlled not to be powered on.

In some embodiments, every time when the individual output pins of the flip-flop each receive one enable signal, the output levels of the individual output pins of the flip-flop are flip-flopped or not flip-flopped, and the individual output pins of the flip-flop maintain the flip-flopped output level or the output level unchanged, till the individual output pins of the flip-flop each receive the next enable signal, such that the individual output pins of the flip-flop can control, based on one enable signal, the individual cameras connected to the individual output pins of the flip-flop to be powered on or not all the time, till the individual output pins of the flip-flop receive the next enable signal, which reduces the number of sending the enable signal by the SOC and saving the resources for the SOC.

In some embodiments, each of the cameras is provided with three power supply circuits, including an analog circuit voltage (AVDD) circuit, a digital voltage (DVDD) circuit, and an interface circuit voltage (DOVDD) circuit in sequence. The AVDD circuit, the DVDD circuit, and the DOVDD circuit are combined and enabled according to a timing sequence to power on the camera. The AVDD, DVDD, and DOVDD circuits of each of the cameras are each connected to one output pin of the flip-flop, for controlling whether to power on the camera by controlling whether to enable the AVDD, DVDD, and DOVDD circuits. For example, when the flip-flop is provided with 12 output pins, the AVDD, DVDD, and DOVDD circuits of a first camera are connected to the first, second, and third output pins of the flip-flop, respectively; the AVDD, DVDD, and DOVDD circuits of a second camera are connected to the fourth, fifth, and sixth output pins of the flip-flop, respectively; the AVDD, DVDD, and DOVDD circuits of a third camera are connected to the seventh, eighth, and ninth output pins of the flip-flop, respectively; and the AVDD, DVDD, and DOVDD circuits of a fourth camera are connected to a tenth, eleventh, and twelfth output pins of the flip-flop, respectively. Accordingly, the SOC may control these 12 output pins to be enabled independently, thereby driving these four cameras independently.

In some embodiments, in a case where the four cameras are all powered off, the SOC sequentially sends 12 path switching signals “1” to the path pin, sequentially sends 12 enable signals “1”, “1”, “1” “0”, “0”, “0” “1”, “1”, “1” “0”, “0”, and “0” (with the enable signal “1” indicating a high level and the enable signal “0” indicating a low level) to the instruction pin, and sends a shift signal “1” to the shift pin, such that the output levels of the first, second, third, seventh, eighth, and ninth output pins of the 12 output pins of the flip-flop are converted from a low level to a high level, and the fourth, fifth, sixth, tenth, eleventh, and twelfth output pins are maintained at the low level, for controlling the first and third cameras to be powered on, and the second and fourth cameras not to be powered on. Here, the input-output module is powered on, and the path switcher, the shift register, and the flip-flop perform resetting and cyclically perform the following steps: turning on, when the path switcher receives the K^{th} (K is an integer greater than or equal to 1 and less than or equal to 12) path switching signal “1” from the path pin, the K^{th} sub-register corresponding to the K^{th} path switch, and transmitting, when the path switcher receives the K^{th} enable signal “1” or “0” from the instruction pin, the K^{th} enable signal “1” or “0” to the K^{th} sub-register, which stores the Kth enable signal “1” or “0”, till the twelfth sub-register stores the twelfth enable signal “0”; receiving a shift signal from the shift pin by the shift register, transmitting the enable signal stored by each of the sub-registers to each of the input pins of the flip-flop, which transmits the enable signals received from the individual input pins to the individual output pins of the flip-flop by means of the individual toggle paths, respectively, and flip-flopping, when the enable signal transmitted to an output pin of the flip-flop is “1”, the output level of said output pin of the flip-flop from the low level into the high level, and maintaining, when the enable signal transmitted to an output pin of the flip-flop is “0”, the output level of said output pin of the flip-flop at the low level, such that the output levels of the first, second, and third output pins of the flip-flop are high, the output levels of the fourth, fifth, and sixth output pins are low, the output levels of the seventh, eighth, and ninth output pins are high, and the output levels of the tenth, eleventh, and twelfth output pins are low, that is, the first and third cameras are powered on and the second and fourth cameras are not powered on. For example, the first and third cameras are both low-resolution cameras, and the second and fourth cameras are both high-resolution cameras. In a case where a user selects an application icon based on a fixation point control menu of the VR/AR apparatus without powering on the high-resolution cameras, the first and third cameras of the low resolution may be controlled to be powered on only, and the second and fourth cameras of the high resolution may be controlled not to be powered on, thereby reducing the power consumption.

In some embodiments, in a case where the first and third cameras are powered on and the second and fourth cameras are not powered on, the SOC sequentially sends 12 path switching signals “1” to the path pin, sends 12 enable signals “0”, “0”, “0”, “1”, “1”, “1”“0”, “0”, “0”“1”, “1”, and “1” to the instruction pin, and sends a shift signal “1” to the shift pin, such that the first, second, third, seventh, eighth, and ninth output pins of the 12 output pins of the flip-flop are maintained at the high level, and the fourth, fifth, sixth, tenth, eleventh, and twelfth output pins are converted from the low level to the high level, which then allows the AVDD, DVDD, and DOVDD circuits of each of the cameras to be enabled, for controlling the second and fourth cameras of the 4 cameras connected to the 12 output pins of the flip-flop to be also powered on, and the first and third cameras to maintain powered-on. For example, after a user enters a movie watching application of the VR/AR apparatus, the high-resolution cameras need to be also powered on since movie watching requires for increased tracking precision of a fixation point. Therefore, the low-resolution first and third cameras are controlled to keep powered on, and the high-resolution second and fourth cameras are controlled to be also powered on.

In some embodiments, in a case where the first, second, third, and fourth cameras are all powered on, the SOC sequentially sends 12 path switching signals “1” to the path pin, sends 12 enable signals “1”, “1”, “1” “1”, “1”, “1” “1”, “1”, “1” “1”, “1”, and “1” to the instruction pin, and sends a shift signal “1” to the shift pin, such that the output levels of the 12 output pins of the flip-flop are all converted from the high level to the low level, for controlling the 4 cameras connected to the 12 output pins of the flip-flop to be all powered off. For example, after the user exists the movie watching application and returns to the desktop of the VR/AR apparatus, there is no need to power on any one of the cameras, and the 4 cameras are all controlled to be powered off.

According to the embodiments of the present disclosure, the input pins of the input-output module has a number less than that of the output pins, each of the output pins of the input-output module is connected to one port of the SOC, respectively, and each of the output pins of the input-output module is connected to a plurality of devices of the apparatus, respectively, such that whether to power on a large number of devices is controlled by only occupying a small number of ports of the SOC, thereby saving the resources for the SOC.

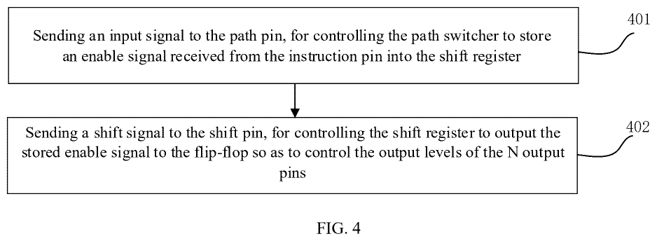

FIG. 4 is a schematic flowchart of a control method according to an embodiment of the present disclosure. As shown in FIG. 4, the control method applied to the input-output module as defined above is exemplified in an embodiment of the present disclosure. The method includes the following steps.

In step 401, an input signal is sent to the path pin, for controlling the path switcher to store an enable signal received from the instruction pin into the shift register.

In some embodiments, the path pin and the instruction pin are connected to one port of the SOC, respectively, for allowing the SOC to send an input signal to the path pin to then control the path switcher to store an enable signal received from the instruction pin into the shift register.

In step 402, a shift signal is sent to the shift pin, for controlling the shift register to output the stored enable signal to the flip-flop so as to control the output levels of the N output pins.

Here, the number of the input pins is less than the number of the output pins.

According to the embodiments of the present disclosure, the input-output module with the output pins having the number greater than that of its input pins is disposed on the ports of the SOC, and the plurality of output pins of the input-output module are connected to a plurality of devices, respectively, whereby whether to power on a large number of devices can be controlled in a case where a small number of ports of the SOC are occupied, thereby saving the resources for the SOC; furthermore, the SOC independently enables each of the output pins of the input-output module, and then allows for independent drive of the plurality of devices connected to the individual output pins, respectively.

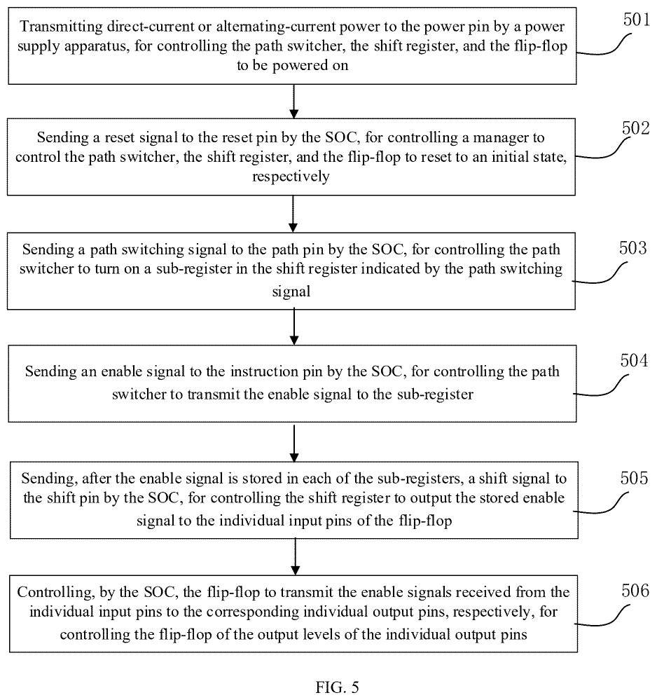

The embodiment shown in FIG. 4 is a brief flow process of the embodiment of the present disclosure. The following further explains the technical solution of the present disclosure based on FIG. 5. FIG. 5 is an exemplary schematic flowchart of a control method according to an embodiment of the present disclosure. The control method applied to the input-output module as defined above is exemplified in an embodiment of the present disclosure. The method includes the following steps.

In step 501, a power supply apparatus transmits direct-current or alternating-current power to the power pin, for controlling the path switcher, the shift register, and the flip-flop to be powered on.

The embodiments of the present disclosure do not make specific definitions to the power supply apparatus.

In step 502, the SOC sends a reset signal to the reset pin, for controlling a manager to control the path switcher, the shift register, and the flip-flop to reset to an initial state, respectively.

In step 503, the SOC sends a path switching signal to the path pin, for controlling the path switcher to turn on a sub-register in the shift register indicated by the path switching signal.

In some embodiments, the SOC sequentially sends a plurality of path switching signals to the path pin, and each of the path switching signals is configured to control the path switcher to turn on one sub-register corresponding to one path switch, thereby turning on each of the sub-registers in the shift register in sequence.

In step 504, the SOC sends an enable signal to the instruction pin by the SOC, for controlling the path switcher to transmit the enable signal to the sub-register.

In some embodiments, every time when sending one path switching signal to the path pin, the SOC then waits for a preset delay for the path switcher to turn on one sub-register corresponding to one path switching switch, and then sends one enable signal to the instruction pin for controlling the path switcher to transmit the enable signal to one sub-register. The embodiments of the present disclosure do not make specific definitions to the preset time delay.

In step 505, after the enable signal is stored in each of the sub-registers, the SOC sends a shift signal to the shift pin by the SOC, for controlling the shift register to output the stored enable signal to the individual input pins of the flip-flop.

In step 506, the SOC controls the flip-flop to transmit the enable signals received from the individual input pins to the corresponding individual output pins, respectively, for controlling the flip-flop of the output levels of the individual output pins.

In some embodiments, when the enable signal received by any one of the output pins of the flip-flop is of a high level, the output level of said output pin of the flip-flop is controlled to be flip-flopped, and the flip-flopped output level is maintained. For example, when the output level of an output pin of the flip-flop is high, the output level is converted from the high level to a low level after flip-flopping, and said output pin of the flip-flop is not enabled; and when the output level of an output pin of the flip-flop is low, the output level is changed from the low level to a high level after flip-flopping, and said output pin of the flip-flop is enabled.

In some embodiments, when the enable signal received by any one of the output pins of the flip-flop is of a low level, the output level of said output pin of the flip-flop is controlled not to be flip-flopped, and the output level is maintained; when the output level is low, said output pin of the flip-flop is not enabled; and when the output level is high, said output pin of the flip-flop is enabled.

In some embodiments, the SOC sends a reset signal to the reset pin, for controlling the path switcher, the shift register, and the flip-flop to reset.

In some embodiments, the power supply apparatus transmits the alternating current or direct current to the power pin, for controlling whether to enable the individual output pins of the flip-flop. The embodiments of the present disclosure do not make specific definitions to the power supply apparatus.

According to the embodiments of the present disclosure, the SOC sends the path switching signal to the path pin of the input-output module, the enable signal to the instruction pin, and the shift signal to the shift pin, to control whether to enable the individual output pins of the input-output module, which in turn controls whether to power on the individual devices connected to the individual output pins of the input-output module, respectively; furthermore, the number of the input pins of the input-output module is less than the number of its output pins, which thus saves the resources for the SOC.

An embodiment of the present disclosure further provides a chip. The chip includes the input-output module as defined above.

An embodiment of the present disclosure further provides a virtual reality apparatus. The virtual reality apparatus includes a plurality of cameras. Each of the cameras is connected to the chip as defined above, respectively, for controlling whether to power on each of the cameras, respectively, by means of the chip.

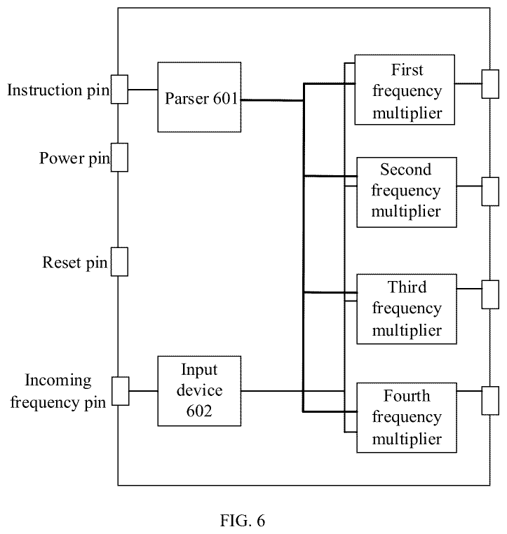

FIG. 6 is a schematic structural diagram of a frequency conversion module according to an embodiment of the present disclosure. As shown in FIG. 6, the module includes a parser 601 and a plurality of frequency multipliers. Each of the frequency multipliers is connected to the parser 601, respectively, and is connected to the device of the apparatus, respectively.

The module further includes an instruction pin to allow the parser 601 to acquire data to be parsed from the instruction pin.

The module further includes a power pin, which is connected to the parser 601 and the plurality of frequency multipliers, respectively, and is configured to supply power to the parser 601 and the plurality of frequency multipliers respectively with the alternating current or direct current transmitted by means of the power pin.

The module further includes a reset pin, which is connected to the parser 601 and the plurality of frequency multipliers, respectively. The parser 601 and the plurality of frequency multipliers receive a reset signal from the reset pin, respectively, and then perform a reset.

The module further includes a plurality of output pins, each of which is in one-to-one correspondence with one device and one frequency multiplier.

In some embodiments, the parser 601 is configured to parse the acquired data to be parsed to acquire a plurality of sets of frequency conversion data, each of which includes an identifier of frequency multiplier and a frequency conversion value; and configured to send each set of the frequency conversion data to a corresponding frequency multiplier, respectively, based on the identifier of frequency multiplier in each set of the frequency conversion data.

In some embodiments, one port of the SOC sends the data to be parsed to the parser 601 by simulating the universal asynchronous receiver/transmitter (UART) protocol. The embodiments of the present disclosure do not make specific definitions to the parser 601 and the frequency multiplier.

In some embodiments, the SOC acquires the input frequency (reference frequency) of a synchronization signal for each device and the tracking frequency required for eye tracking; the SOC calculates the frequency conversion value of each device, respectively, based on the input frequency and the tracking frequency of each device; and the devices are in one-to-one correspondence with the frequency multipliers. For example, the devices are cameras, and the display state of the display module of the VR/AR apparatus is associated with each camera for eye tracking, respectively; after a user turns on the VR/AR apparatus and the screen of the VR/AR apparatus lights up, the SOC acquires the input frequency of the synchronization signal; when the user starts an application icon by means of a fixation point control menu on the screen, the SOC acquires the tracking frequency of each camera according to the display state of the display module combined with a tracking algorithm; and the SOC calculates the input frequency and tracking frequency of each camera to acquire the frequency conversion value of each camera, and sends the individual frequency conversion values and identifier of frequency multipliers to the parser 601. Here, when the frequency conversion value is greater than 1, it means that the tracking frequency is greater than the input frequency; when the frequency conversion value is equal to 1, it means that the tracking frequency is equal to the input frequency; when the tracking frequency is less than 1 or greater than 0, it means that the tracking frequency is less than the input frequency; and when the frequency conversion value is equal to 0, it means that the tracking frequency is equal to 0.

In some embodiments, the frequency multipliers multiply the received input frequencies based on to the received frequency conversion values.

According to the embodiments of the present disclosure, one parser 610 receives the frequency conversion values of the individual frequency multipliers as sent by the SOC, and then sends the individual frequency conversion values to the individual frequency multipliers, respectively, such that the plurality of frequency multipliers is controlled by means of one parser 601 to multiply the input frequencies, which solves the problem that differentiated outputs cannot be sent to the plurality of devices by means of a single reference frequency.

In some embodiments, each of the frequency multipliers is configured to multiply the input frequency based on the received frequency conversion value to acquire a target frequency, which represents the operating frequency of the device.

In some embodiments, the individual frequency multipliers transmit the individual target frequencies (equal to the tracking frequencies) to the individual device by means of the individual input pins, for controlling the operating frequencies of the individual devices. For example, if the input frequency is P, when a user selects an application icon based on the fixation point control menu of the VR/AR apparatus to launch a shooting game, each camera needs a higher tracking frequency after entering the game, with the tracking frequency of the first camera being 2P, the tracking frequency of the second camera being 3P, the tracking frequency of the third camera being 4P, and the tracking frequency of the fourth camera being 5P; the SOC acquires the frequency conversion values (which are 2, 3, 4 and 5, respectively) of the individual cameras, and sends the data to be parsed to the parser 601 for parsing to acquire: a frequency conversion value 2 and the identifier of a first frequency multiplier, a frequency conversion value 3 and the identifier of a second frequency multiplier, a frequency conversion value 4 and the identifier of a third frequency multiplier, a frequency conversion value 5 and the identifier of a fourth frequency multiplier; the parser 601 sends the above parsing results to the individual frequency multipliers, respectively; and the individual frequency multipliers multiply the input frequencies, respectively, based on the received frequency conversion values to output target frequencies 2P, 3P, 4P and 5P, thereby controlling the first camera to perform exposure at the target frequency 2P, the second camera to perform exposure at the target frequency 3P, the third camera to perform exposure at the target frequency 4P, and the fourth camera to perform exposure at the target frequency 5P. When the user ends the game and is ready to turn off the VR/AR apparatus, the tracking frequency of each camera is 0, and each frequency multiplier multiply the input frequency, respectively, based on the received frequency conversion value of 0 to output the target frequency of 0, thereby controlling the first, second, third, and fourth cameras not to perform exposure. According to the embodiment of the present disclosure, each camera can be controlled to perform exposure at a specific time and at a specific tracking frequency.

In some embodiments, the module further includes an input device 602. The input device 602 is connected to each of the frequency multipliers, respectively, and is configured to transmit said input frequency to each of the frequency multipliers, respectively.

Here, the module further includes an incoming frequency pin for allowing the input device 602 to receive the input frequency from the incoming frequency pin.

In some embodiments, the module further includes an enabler 702. The input terminal of the enabler 702 is connected to at least one of the devices, and the output terminal of the enabler 702 is connected to at least one fill light 703.

The enabler 702 is configured to enable the fill light 703.

In some embodiments, as shown in FIG. 7, the enabler 702 is disposed between the fill light 703 and a drive power supply 701 of the fill light 703, and is configured such that the fill light 703 is lit only when the enabler 702 is enabled. For example, if the device is a camera, when the camera performs exposure at any exposure frequency, a strobe signal is output, the enabler 702 is enabled after receiving the strobe signal, the fill light 703 is lit, thereby filling light for the camera; and after the exposure of the camera ends without the output of the strobe signal, the enabler 702 is not enabled, and the fill light 703 is turned off. According to the embodiment of the present disclosure, the fill light 703 is only controlled to fill light for the camera when the camera performs exposure, which reduces the power consumption. The embodiments of the present disclosure do not make specific definitions to the enabler 702.

According to the embodiment of the present disclosure, the plurality of frequency multipliers is controlled by means of one parser to multiply the input frequency, respectively, which solves the problem that differentiated outputs cannot be sent to a plurality of devices by means of a single reference frequency; furthermore, the operating frequency of each camera is switched based on the real-time tracking frequency of eye tracking, without the need of controlling the operating frequency of each camera all the time by one port of the SOC, such that the resources are saved for the SOC.

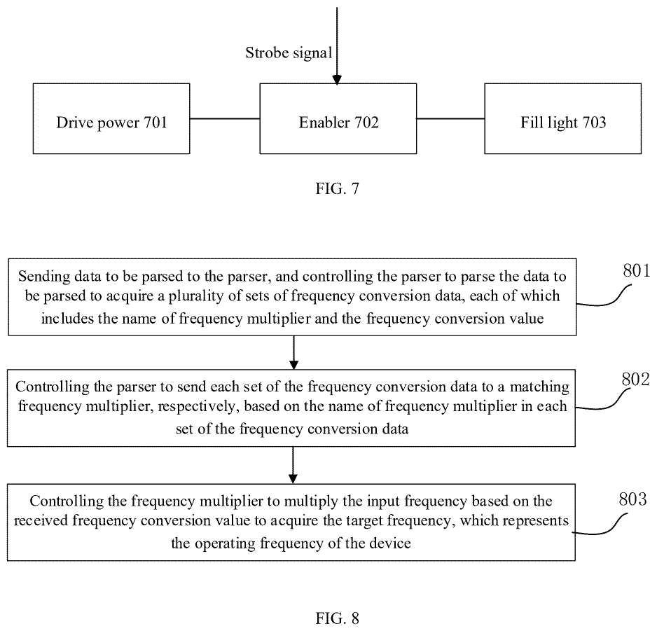

FIG. 8 is a schematic flowchart of a control method according to an embodiment of the present disclosure. As shown in FIG. 8, the control method applied to the frequency conversion module as defined above is exemplified in an embodiment of the present disclosure. The method includes the following steps.

In step 801, data to be parsed are sent to the parser, and the parser is controlled to parse the data to be parsed to acquire a plurality of sets of frequency conversion data, each of which includes the identifier of frequency multiplier and the frequency conversion value.

In step 802, the parser is controlled to send each set of the frequency conversion data to a matching frequency multiplier, respectively, based on the identifier of frequency multiplier in each set of the frequency conversion data.

In step 803, the frequency multiplier is controlled to multiply the input frequency based on the received frequency conversion value to acquire the target frequency, which represents the operating frequency of the device.

According to the embodiment of the present disclosure, the SOC sends the frequency conversion values of the individual frequency multipliers to one parser, and controls the plurality of frequency multipliers to multiply the input frequency based on the individual frequency conversion values, respectively, to acquire a plurality of target frequencies, thereby solving the problem that differentiated outputs cannot be sent to a plurality of devices by means of a single reference frequency. Furthermore, the operating frequencies of individual devices are switched based on the tracking frequency of real-time eye tracking, and there is no need to control the operating frequencies of the individual devices all the time by the ports of the SOC, thereby saving SOC resources.

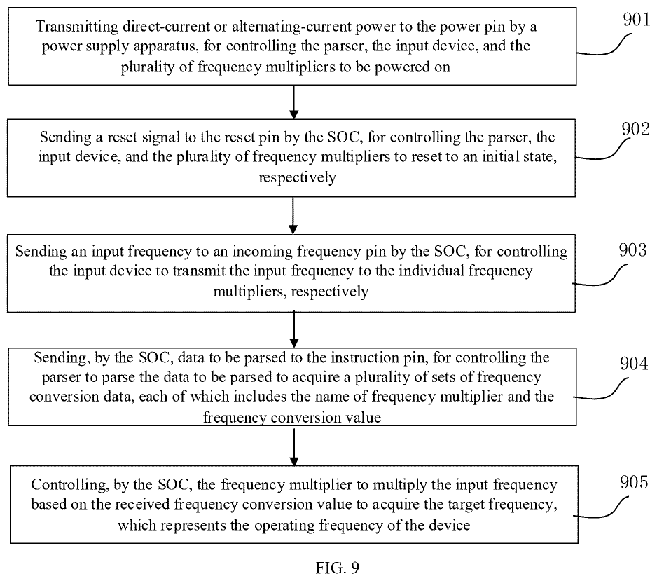

The embodiment shown in FIG. 8 is a brief flow process of the embodiment of the present disclosure. The following further explains the technical solution of the present disclosure based on FIG. 9. FIG. 9 is an exemplary schematic flowchart of a control method according to an embodiment of the present disclosure. The control method applied to the frequency conversion module as defined above is exemplified in an embodiment of the present disclosure. The method includes the following steps.

In step 901, the power supply apparatus transmits direct-current or alternating-current power to the power pin by a power supply apparatus, for controlling the parser, the input device, and the plurality of frequency multipliers to be powered on.

Here, the power pin includes a power voltage (VDD) pin and a ground (GND) pin.

The embodiments of the present disclosure do not make specific definitions to the power supply apparatus.

In step 902, the SOC sends a reset signal to the reset pin, for controlling the parser, the input device, and the plurality of frequency multipliers to reset to an initial state, respectively.

In step 903, the SOC sends an input frequency to an incoming frequency pin, for controlling the input device to transmit the input frequency to the individual frequency multipliers, respectively.

In step 904, the SOC sends data to be parsed to the instruction pin, for controlling the parser to parse the data to be parsed to acquire a plurality of sets of frequency conversion data, each of which includes the identifier of frequency multiplier and the frequency conversion value.

In step 905, the SOC controls the frequency multiplier to multiply the input frequency based on the received frequency conversion value to acquire the target frequency, which represents the operating frequency of the device.

According to the embodiment of the present disclosure, the SOC sends the frequency conversion values of the individual frequency multipliers to one parser, and controls the plurality of frequency multipliers to multiply the input frequency based on the individual frequency conversion values, respectively, to acquire a plurality of target frequencies, thereby solving the problem that differentiated outputs cannot be sent to a plurality of devices by means of a single reference frequency. Furthermore, the operating frequencies of individual devices are switched based on the tracking frequency of real-time eye tracking, and there is no need to control the operating frequencies of the individual devices all the time by the ports of the SOC, thereby saving SOC resources.

According to a seventh aspect of the embodiments of the present disclosure, a chip is provided. The chip includes the frequency conversion module as defined above.

An embodiment of the present disclosure further provides a virtual reality apparatus. The virtual reality apparatus includes the chip as defined above.

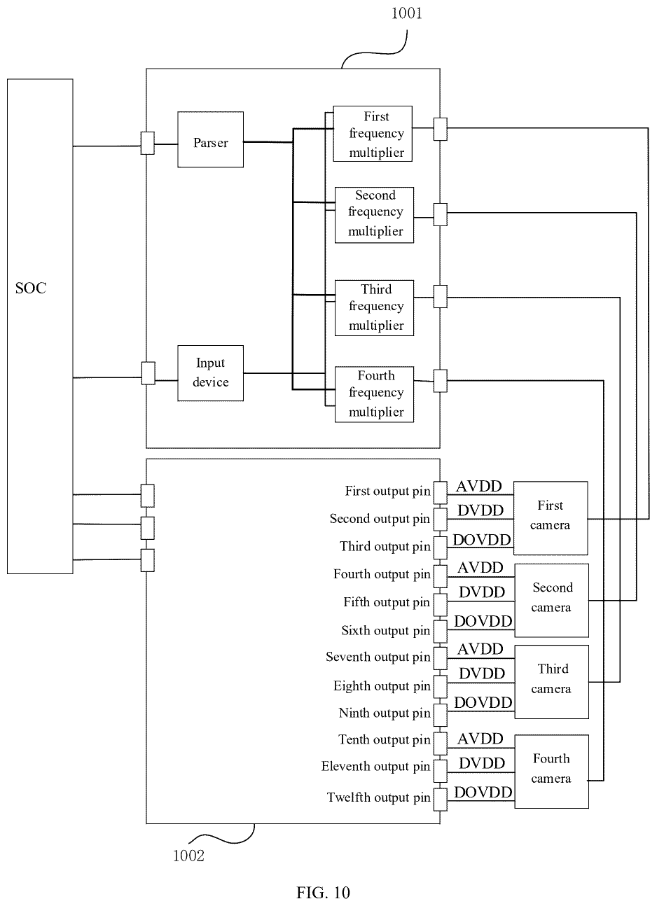

In some embodiments, the SOC in the VR/AR apparatus is connected to the input-output module 1002 and the frequency conversion module 1001, respectively, and each camera is connected to the input-output module 1002, the frequency conversion module 1001, and the enabler, respectively. After the input-output module 1002 controls each camera to be powered on, if the frequency conversion module 1001 outputs the target frequency to each camera, each camera performs exposure based on the target frequency (i.e., the exposure frequency); during the exposure, each camera outputs the strobe signal to the corresponding enabler to enable the enabler, thereby turning on the fill light connected to the enabler; and the fill light fills light for the camera performing the exposure, such that after the input-output module 1002 controls each camera to be powered on, the frequency conversion module 1001 controls the powered-on camera to perform exposure, and the camera performing the exposure turns on the corresponding fill light, thereby allowing for filling light only for the camera performing exposure, which reduces the energy consumption. For example, as shown in FIG. 10, when the output levels of the first, second, third, fourth, fifth, sixth, seventh, eighth, ninth, tenth, eleventh, and twelfth output pins are all high, the AVDD, DVDD, and DOVDD circuits of each of the cameras are enabled to then control all the 4 cameras to be powered on. The parser transmits, to the first, second, third, and fourth frequency multipliers, the frequency conversion values corresponding to the individual frequency multipliers. Based on the received frequency conversion values, the individual frequency multipliers multiply the input frequencies received from the input device, to acquire a first target frequency by the first frequency multiplier, a second target frequency by the second frequency multiplier, a third target frequency by the third frequency multiplier, and a fourth target frequency by the fourth frequency multiplier. Then, the first frequency multiplier transmits the first target frequency to the first camera, which performs exposure based on the first target frequency, the second frequency multiplier transmits the second target frequency to the second camera, which performs exposure based on the second target frequency, the third frequency multiplier transmits the third target frequency to the third camera, which performs exposure based on the third target frequency, and the fourth frequency multiplier transmits the fourth target frequency to the fourth camera, which performs exposure based on the fourth target frequency. During the exposures performed by the first, second, third, and fourth cameras, corresponding fill lights are turned on to fill light respectively for the first, second, third, and fourth cameras performing the exposures.

Those of ordinary skills in the art can understand that all or some of the steps in the above embodiments may be implemented by hardware, or by a program to instruct related hardware. The program may be stored in a computer-readable storage medium. The above storage medium may be a read-only memory, a magnetic disk or an optical disk or the like.

Described above are merely exemplary embodiments of the present disclosure, and are not intended to limit the present disclosure. Within the spirit and principles of the present disclosure, any modifications, equivalent substitutions, improvements, and the like are within the protection scope of the present disclosure.

1. An input-output module having M input pins, a path switcher, a shift register and a flip-flop connected in sequence, the flip-flop having N output pins;
wherein the M input pins are configured to receive input signals, and the M input pins comprise a path pin, an instruction pin, and a shift pin, the N output pins are configured to be connected to a plurality of devices of an apparatus, respectively, output levels of the N output pins are configured to control whether to power on the plurality of devices or not, and M and N are positive integers; and
the path switcher is configured to store, in response to an input signal of the path pin, an enable signal received from the instruction pin into the shift register, and the shift register is configured to output, in response to a shift signal of the shift pin, the stored enable signal to the flip-flop to control the output levels of the N output pins.

2. The module according to claim 1, wherein M is less than N.

3. The module according to claim 1, wherein the shift register comprises a plurality of sub-registers, the path switcher comprises a plurality of path switches in one-to-one correspondence with the sub-registers;
the path switcher is configured to receive a path switching signal from the path pin, and turn on a path switch indicated by the path switching signal to turn on a sub-register in the shift register corresponding to the path switch;
the path switcher is configured to receive the enable signal from the instruction pin, and transmit the enable signal to the sub-register; and
the shift register is configured to receive the shift signal from the shift pin, and output the stored enable signal to the flip-flop.

4. (canceled)

5. The module according to claim 1 claim 3, wherein the output pins comprised by the flip-flop are in one-to-one correspondence with the sub-registers, and the flip-flop is configured to flip-flop, in a case where an enable signal received from any one of the sub-registers is of a high level, an output level of a corresponding output pin; or, the flip-flop is configured to maintain, in a case where an enable signal received from any of the sub-registers is of a low level, an output level of the corresponding output pin.

6. A control method applied to the input-output module according to claim 1, comprising:
sending an input signal to the path pin, for controlling the path switcher to store the enable signal received from the instruction pin into the shift register; and
sending a shift signal to the shift pin, for controlling the shift register to output the stored enable signal to the flip-flop so as to control the output levels of the N output pins.

7. The method according to claim 6, wherein sending the input signal to the path pin, for controlling the path switcher to store the enable signal received from the instruction pin into the shift register, and sending the shift signal to the shift pin, for controlling the shift register to output the stored enable signal to the flip-flop so as to control the output levels of the N output pins, comprises:
sending a path switching signal to the path pin, for controlling the path switcher to turn on a sub-register in the shift register indicated by the path switching signal;
sending an enable signal to the instruction pin, for controlling the path switcher to transmit the enable signal to the sub-register; and
sending a shift signal to the shift pin, for controlling the shift register to output the stored enable signal to the flip-flop so as to control the output levels of the N output pins.

8. The method according to claim 6, wherein outputting the stored enable signal to the flip-flop so as to control the output levels of the N output pins comprises:
when the enable signal received by the flip-flop from any sub-register is of a high level, controlling the flip-flop to flip-flop an output level of the corresponding output pin; and
when the enable signal received by the flip-flop from any sub-register is of a low level, controlling the flip-flop to maintain an output level of the corresponding output pin.

9. A chip comprising the input-output module according to claim 1.

10. (canceled)

11. A frequency conversion module, comprising:
a parser and a plurality of frequency multipliers, wherein each of the frequency multipliers is connected to the parser, respectively;
the parser is configured to parse acquired data to be parsed to acquire a plurality of sets of frequency conversion data, each of which comprises an identifier of frequency multiplier and a frequency conversion value, and configured to send, based on the identifier of frequency multiplier in each set of the frequency conversion data, each set of the frequency conversion data to a corresponding frequency multiplier, respectively; and
each of the frequency multipliers is configured to multiply an input frequency by a factor which is determined by the received frequency conversion value.

12. The module according to claim 11, further comprising an input device, wherein the input device is connected to each of the frequency multipliers, respectively, and is configured to transmit the input frequency to each of the frequency multipliers, respectively.

13. The module according to claim 11, further comprising an enabler, wherein an input terminal of the enabler is connected to at least one of the devices, and an output terminal of the enabler is connected to at least one fill light; and
the enabler is configured to enable the fill light.

14. A control method applied to the frequency conversion module according to claim 11, comprising:
sending data to be parsed to the parser, and controlling the parser to parse the data to be parsed to acquire the plurality of sets of frequency conversion data, each of which comprises the name of frequency multiplier and the frequency conversion value;
controlling the parser to send each set of the frequency conversion data to a matching frequency multiplier, respectively, based on the name of frequency multiplier in each set of the frequency conversion data; and
controlling the frequency multiplier to multiply the input frequency by the factor which is determined by the received frequency conversion value.

15. (canceled)

16. A chip, comprising the frequency conversion module according to claim 11.

17. (canceled)

18. An input-output module having M input pins and N output pins, wherein the M input pins comprise a path pin, an instruction pin and a shift pin, and the input-output module comprises: a path switcher having an input terminal, a path terminal and N output terminals, a shift register having a shift terminal, N input terminals and N output terminals, and a flip-flop having N input terminals and N output terminals; wherein
the input terminal of the path switcher is connected to the instruction pin, the path terminal of the path switcher is connected to the path pin, the N output terminals of the path switcher are connected to the N input terminals of the shift register in one to one correspondence, the path switcher is configured to transmit an enable signal provided by the path pin to one of the N output terminals of the path switcher which is indicated by a path switching signal provided by the instruction pin;
the shift terminal of the shift register is connected to the shift pin, the N input terminals of the shift register are connected to the N output terminals of the path switcher in one-to-one correspondence, the N output terminals of the shift register are connected to the N input terminals of the flip-flop in one-to-one correspondence, the N input terminals of the shift register are in one-to-one correspondence with the N output terminals of the shift register, the shift register is configured to: receive at least one enable signal from at least one of the N input terminals of the shift register before a shift signal provided by the shift pin is received, and, send the at least one enable signal to at least one corresponding output terminal of the shift register when the shift signal provided by the shift pin is received; and
the N output terminals of the flip-flop are connected to the N output pins in one-to-one correspondence, the N input terminals of the flip-flop are in one-to-one correspondence with the N output terminals of the flip-flop, and the flip-flop is configured to receive at least one enable signal from at least one of the N input terminals of the flip-flop, and flip an output level of at least one corresponding output terminal of the flip-flop.

19. The input-output module according to claim 18, wherein M is less than N, the shift register comprises N sub-registers, the path switcher comprises N path switches in one-to-one correspondence with the sub-registers; each of the path switches is connected to the path terminal of the path switcher and one of the N output terminals of path switcher, respectively, and each of the sub-registers is connected to the shift pin terminal, one of the N input terminals of the shift register, and one of the N output terminals of shift register, respectively.

20. The input-output module according to claim 19, wherein the sub-register is configured to: receive an enable signal from a corresponding input terminal of the shift register before a shift signal provided by the shift terminal is received, and, send the enable signal to a corresponding output terminal of the shift register when the shift signal provided by the shift terminal is received.

21. The input-output module according to claim 18, wherein each of the output levels of the N output pins is flipped between a high potential level and a low potential level, and the flip-flop is configured to maintain an output level of each of the N output terminals of the flip-flop before an enable signal from a corresponding input terminal of the flip-flop is received.

22. The input-output module according to claim 18, wherein the M input pins further comprise a reset pin, the manager is respectively connected to the reset pin, the path switcher, the shift register and the flip-flop, and the manager is configured to control each of the path switcher, the shift register and the flip-flop to perform resetting in response to a reset signal from the reset pin.

23. A control method applied to the input-output module according to claim 18, comprising:
sending an enable signal to the path pin and sending a path switching signal to the instruction pin, such that the path switcher transmits the enable signal provided by the path pin to one of the N input terminals of the shift register which is indicated by the path switching signal provided by the instruction pin; and
sending a shift signal to the shift pin, such that the shift register sends at least one enable signal to at least one corresponding input terminal of the flip-flop to flip an output level of at least one corresponding output pin.

24. A chip comprising the input-output module according to claim 18.
